(19) United States
(12) Patent Application Publication
(10) Pub. No.: US 2020/0227351 A1
(43) Pub. Date: Jul. 16, 2020

(54) INTEGRATED CIRCUIT CHIP

(71) Applicant: Dolphin Design, Meylan (FR)

(72) Inventors: Amir MORSHEDEIAN, Laval (CA); Nicolas LAFLAMME-MAYER, Laval (CA); Mathieu RENAUD, Laval (CA); Sébastien GENEVEY, Gieres (FR)

(21) Appl. No.: 16/580,146

(22) Filed: Sep. 24, 2019

(30) Foreign Application Priority Data
Sep. 25, 2018 (FR) 18/58748

(51) Int. Cl. H01L 23/528; H01L 27/02; H02H 9/04

(52) U.S. Cl. CPC H01L 23/5286; H02H 9/046; H01L 27/0251

(57) ABSTRACT

The present description relates to an integrated circuit (100) comprising a power rail (112) having two types of rail segments, rail segments of a first type (112-ON) being able to be activated selectively relative to rail segments of a second type (112-OFF).

### CROSS-REFERENCE TO RELATED APPLICATIONS

Priority is claimed from the French patent application assigned filing number FR18/58748 filed on Sep. 25, 2018, the contents of which is hereby incorporated by reference. To the extent that the present disclosure conflicts with any referenced application, however, the present disclosure is to be given priority

### TECHNICAL FIELD

The present description generally relates to electronic circuits, and more particularly integrated circuits. The present description applies to the production of integrated circuits and the reduction of their energy consumption.

### BACKGROUND OF THE INVENTION

Integrated circuits are circuits comprising electronic components incorporating more or less complex functions, and used in electronic devices.

In order to reduce their energy consumption, most integrated circuits use several different supply modes, in particular one or several standby modes in which the power supply of certain components is reduced.

It would be desirable to be able to reduce the energy consumption of the integrated circuits, and more particularly to reduce the consumption of the standby modes of integrated circuits.

### SUMMARY

One embodiment provides an integrated circuit comprising a power rail having two types of rail segments, rail segments of a first type being able to be activated selectively relative to rail segments of a second type.

According to one embodiment, the rail segments of the first type can be activated selectively by group.

According to one embodiment, the rail segments of the first type can be activated by means of a switch.

According to one embodiment, the switch is controlled by at least one unit supplied by one or several rail segments of the second type.

According to one embodiment, the switch is a discrete component mounted on the integrated circuit (chip).

According to one embodiment, the switch is integrated in the integrated circuit (chip).

According to one embodiment, the switch is controlled by a circuit able to control the activation speed of the rail segments of the first type.

According to one embodiment, the rail segments of the first type can be activated by means of a regulator.

According to one embodiment, the regulator is controlled by at least one unit supplied by the rail segments of the second type.

According to one embodiment, the regulator is controlled by means of a circuit able to control the activation speed of the rail segments of the first type.

According to one embodiment, the regulator is a discrete component mounted on the integrated circuit (chip).

According to one embodiment, the circuit is formed in and on a structure of the silicon-on-insulator type comprising a front side comprising the power rail, and a back side made from silicon, opposite the front side.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a simplified electrical diagram of one embodiment of an integrated circuit;

FIG. 2 is a more detailed electrical diagram of the integrated circuit of FIG. 1; and

FIG. 3 groups together partial electrical diagrams illustrating embodiments 3A to 3C of the integrated circuit of FIG. 1.

### DETAILED DESCRIPTION OF THE INVENTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements linked or coupled together, this signifies that these two elements can be connected or they can be linked or coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

FIG. 1 is a simplified electrical diagram of one embodiment of an integrated circuit 100, comprising a power ring 110 and functional units powered by the power ring 110. The functional units are circuits performing more or less complex functions that will not be described in detail in this description. The power ring 110 is arranged in loop form on the chip of the integrated circuit 100. In other words, the power ring 110 is arranged on the periphery of the chip of the integrated circuit 100. The functional blocks are arranged inside the loop formed by the ring 110.

The ring 110 comprises, in this example, a power rail 112 configured to supply a supply potential VDD, for example positive, and a ground rail 114 configured to supply a reference potential GND, for example the ground. The ring 110 can comprise more than two rails. As an example, the ring can further comprise a second supply rail for example supplying a negative supply potential or a second positive potential different from VDD. Each rail 112, 114 comprises connection pads 112P, 114P, or contacts, configured to be connected to terminals of the functional units. In order to protect the functional units against electrostatic discharges, a device protecting against electrostatic discharges 116 links each pad 112P to a pad 114P. In FIG. 1, the pads 112P are shown as being positioned outside the ring 110; in practice, certain pads 112P are positioned outside the ring 110 and make it possible to supply the power rail 112, and other pads 112P are positioned inside the ring 110 and make it possible to supply the functional units.

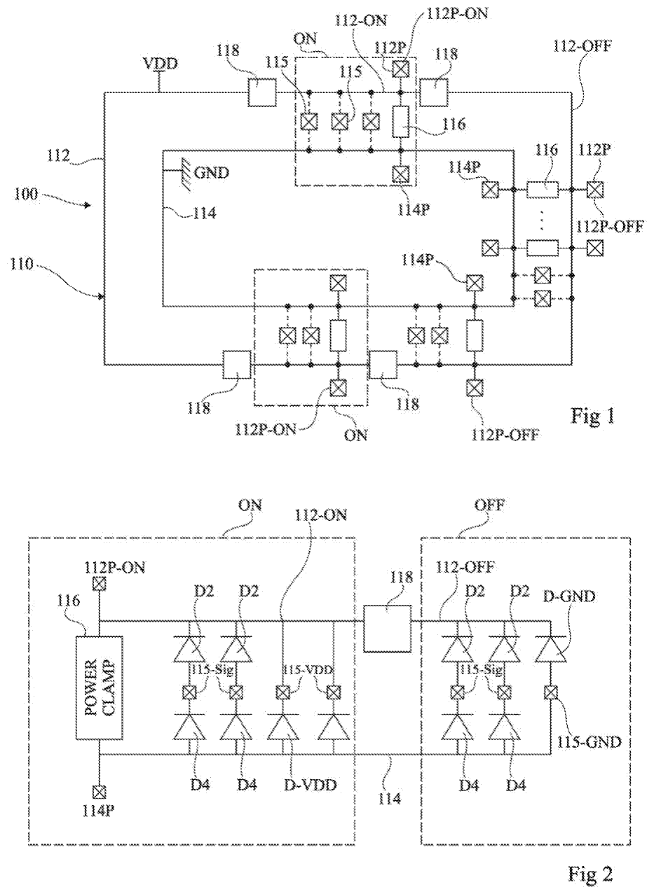

The ring 110 further comprises several terminals 115 coupled to the rails 112 and 114. The terminals 115 are not coupled and/or connected to one another. The terminals 115 and their connection to the rails 112 and 114 will be described in more detail in connection to FIG. 2.

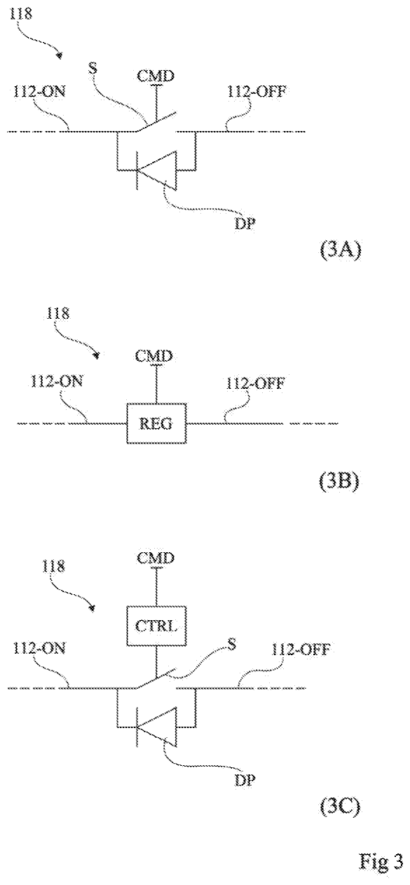

In order to reduce the energy consumption of the integrated circuit 100, there are at least two supply modes of the integrated circuit 100, a full-power supply mode and at least one partial supply mode, or standby mode, or low consumption mode. In the full-power supply mode, all of the functional units are supplied. In the standby mode, the supply of certain functional units is cut. To that end, it is provided to disconnect the power rail 112 coupled to the functional units not used in standby mode. In other words, certain segments of the supply rail 112 can be activated and deactivated selectively, while others are always activated. The segments of the rail 112 that are always activated supply, for example, functional units and are part of ON groups designated in FIG. 1 by dotted lines, and will be referred to hereinafter as segments 112-ON. An ON group comprises pads 112P-ON, pads 114P, protection devices 116 and terminals 115 supplied by a segment 112-ON. Furthermore, the pads 112P intended to supply the rail 112 are always part of an ON group. An integrated circuit may comprise one or several ON groups. The ON groups are delimited by components 118 connected in series on the rail 112. The ON groups can be selected by group. During a standby mode, the components 118 disconnect, from the segment of the rail 112, the pads 112P not belonging to an ON group and thus the functional units that they supply are no longer supplied. The pads 112P will be referenced 112P-OFF hereinafter. The components 118 are controlled by functional units that are always supplied, i.e., by functional units connected to rail segments 112-ON. Examples of components 118 are described in more detail in connection with FIG. 3.

FIG. 2 is a more detailed electrical diagram of a portion of the power ring 110 of the circuit 100 described in connection with FIG. 1.

The portion illustrated in FIG. 2 comprises a pad 112P-ON connected to a rail segment 112, and its associated pad 114P, as well as the device protecting against electrostatic discharges 116 linking them. In FIG. 2, the device 116 is shown in the form of a block (“POWER CLAMP”). The device 116 could be any type of standard device protecting against electrostatic discharges.

This portion further comprises several terminals 115-Sig for applying signals, several terminals for applying a supply voltage 115-VDD and a terminal for applying a reference voltage 115-GND. Each terminal 115-Sig is coupled to the supply rails 112 and 114.

Each terminal 115-Sig is coupled to the power rail 112 by means of a diode D2, and is coupled to the supply rail 114 by means of a diode D4. More particularly, the anode of the diode D2 is coupled, preferably connected, to the terminal 115-Sig, and its cathode is coupled, preferably connected, to the power rail 112. Furthermore, the anode of the diode D4 is coupled, preferably connected, to the power rail 114, and its cathode is coupled, preferably connected, to the terminal 115-Sig.

Each terminal 115-VDD is coupled, preferably connected, to the power rail 112, and is coupled to the rail 114 by means of a diode D-VDD. More particularly, the anode of the diode D-VDD is coupled, preferably connected, to the rail 114, and the cathode of the diode D-VDD is coupled, preferably connected, to the terminal 115-VDD.

The terminal 115-GND is coupled, preferably connected, to the rail 114, and is coupled to the power rail 112 by means of a diode D-GND. More particularly, the anode of the diode D-GND is coupled, preferably connected, to the terminal 115-GND, and the cathode of the diode D-GND is coupled, preferably connected, to the rail 112.

The pad 112P-ON is part of a group further comprising two terminals 115-Sig for applying signals and two terminals 115-VDD for applying a supply voltage. A component 118 separates the group ON from a group OFF composed of a rail 112-OFF connected to the device 118, at least two other terminals 115-Sig for applying signals connected between the power rail 112-OFF and the power rail 114, and a terminal 115-GND.

FIG. 3 schematically shows electrical diagrams 3A to 3C of exemplary embodiments of the component 118.

The diagram 3A illustrates an embodiment of a component 118 comprising a power switch S in series with the rail 112. The switch S is controlled via a signal CMD by a functional block of the integrated circuit 100 (not shown in FIG. 3A) that is always supplied. The component 118 further comprises, for example, a diode DP in parallel with the switch S. The cathode of the diode DP is coupled to the rail segment 112-ON on the ON group side, whereas its anode is coupled to the rail segment 112-OFF. The presence of the diode DP is not mandatory when devices are present protecting against electrostatic discharges 116.

According to one embodiment, the power switch S is added to pre-existing integrated circuits in the form of discrete components connected on the chip of the integrated circuit 100.

According to an alternative embodiment, the power switch S is integrated directly in the chip of the integrated circuit 100.

The diagram 3B illustrates another embodiment of a component 118 comprising a voltage regulator REG in series with the rail 112. The input of the voltage regulator is coupled to the rail segment 112-ON whereas its output is coupled to the rail segment 112-OFF. The regulator R is controlled via a signal CMD by a functional block of the integrated circuit 100 (not shown in FIG. 3B) that is always supplied.

According to one embodiment, the regulator R is added to pre-existing integrated circuits in the form of discrete components connected on the chip of the integrated circuit.

The diagram 3C illustrates an embodiment of the integrated circuit 100 in which the component 118 is controlled via a signal CMD by means of a circuit CTRL capable of controlling the speed of rising of the voltage of the power rail 112-OFF. In FIG. 3C, the component 118 comprises a power switch as illustrated in FIG. 3A, but as a variant, could be a regulator as illustrated in FIG. 3B.

A power switch can open and close very quickly. One of these operations can for example take between 10 and 100 ns. One drawback of this speed is that overly fast closing can create voltage and current peaks that may trigger the devices protecting against electrostatic discharges 116. The circuit CTRL allows this problem to be resolved by slowing the closing of the component 118.

According to one embodiment, an integrated circuit of the type described in connection with FIG. 1 can be formed on an integrated circuit chip comprising a structure of the silicon on insulator (SOI) type. One advantage of this embodiment is that a polarization of the back side of a chip of this type can make it possible to reduce the leakage currents of the components 118 and of the functional units connected to the ring 110.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. An integrated circuit (100) comprising a power rail (112) having two types of rail segments, rail segments of a first type (112-OFF) being able to be activated selectively relative to rail segments of a second type (112-ON).

2. The circuit according to claim 1, wherein the rail segments of the first type (112-OFF) can be activated selectively by group.

3. The circuit according to claim 1, wherein the rail segments of the first type (112-OFF) can be activated by means of a switch (S).

4. The circuit according to claim 3, wherein the switch (S) is controlled by at least one unit supplied by one or several rail segments of the second type (112-ON).

5. The circuit according to claim 3, wherein the switch (S) is a discrete component mounted on the integrated circuit.

6. The circuit according to claim 3, wherein the switch (S) is integrated in the integrated circuit.

7. The circuit according to claim 3, wherein the switch (S) is controlled by a circuit (CTRL) able to control the activation speed of the rail segments of the first type.

8. The circuit according to claim 1, wherein the rail segments of the first type (112-OFF) can be activated by means of a regulator (REG).

9. The circuit according to claim 8, wherein the regulator (R) is controlled by at least one unit supplied by the rail segments of the second type (112-ON).

10. The circuit according to claim 8, wherein the regulator (REG) is controlled by means of a circuit (CTRL) able to control the activation speed of the rail segments of the first type.

11. The circuit according to claim 8, wherein the regulator (REG) is a discrete component mounted on the integrated circuit.

12. The circuit according to claim 1, formed in and on a structure of the silicon-on-insulator type comprising a front side comprising the power rail, and a back side made from silicon, opposite the front side.
